(19) United States
(12) Patent Application Publication
(10) Pub. No.: US 2012/0081166 A1
(43) Pub. Date: Apr. 5, 2012

(54) Level Shifter Circuits and Methods

(75) Inventor: Dieter Draxelmayr, Villach (AT)

(73) Assignee: Infineon Technologies AG, Neubiberg (DE)

(21) Appl. No.: 12/894,320

(22) Filed: Sep. 30, 2010

(51) Int. Cl. H03L 5/00

(52) U.S. Cl. 327/333

(57) ABSTRACT

Some embodiments of the present disclosure relate to a level shifter that provides improved response time and/or low static power dissipation compared to conventional level shifters. In some embodiments, a level shifter circuit includes an input terminal coupled to a first semiconductor device, and an output terminal coupled to a second semiconductor device. The first semiconductor device is designed to operate over a first voltage range associated with an input signal, and the second semiconductor device is designed to operate over a second, different voltage range associated with an latched output signal. To transform the input voltage range to the output voltage range, the level shifter circuit includes a signal analyzer and an output latch, wherein the signal analyzer includes at least one state change element for setting a voltage level of the latched output signal.

Semiconductor devices from one technology generation often have to interface with semiconductor devices from another technology generations or with semiconductor devices of the same technology generation having different power requirements. In either case, in order to ensure proper interfacing between different voltage levels, modern semiconductor devices can include level shifters that are capable of converting voltages from one voltage domain (e.g., 0 V to 5 V domain) to another voltage domain (e.g., 10 V to 15 V domain).

Although conventional level shifters are known, conventional level shifters can suffer from slow response times and undesirable static power dissipation. The present disclosure describes level shifter circuits having improved operating characteristics.

### DESCRIPTION OF THE DRAWINGS

FIG. 1A is a block diagram illustrating a level shifter circuit in accordance with some embodiments.

FIG. 1B illustrates a sample timing diagram discussed in the context of FIG. 1A's embodiment.

FIG. 2A is a circuit schematic illustrating a level shifter circuit in accordance with some embodiments.

FIG. 2B illustrates a sample timing diagram discussed in the context of FIG. 2A's embodiment.

FIG. 3 is a block diagram illustrating another embodiment of a level shifter circuit in accordance with some embodiments.

FIG. 4 illustrates a sample timing diagram discussed in the context of FIG. 3's embodiment.

FIG. 5 is a block diagram illustrating another embodiment of a level shifter circuit in accordance with some embodiments.

FIG. 6 is a block diagram illustrating another embodiment of a level shifter circuit in accordance with some embodiments.

FIG. 7 is a block diagram illustrating another embodiment of a level shifter circuit in accordance with some embodiments.

FIG. 8 is a block diagram illustrating another embodiment of a level shifter circuit in accordance with some embodiments.

FIG. 9 is a block diagram illustrating another embodiment of a level shifter circuit in accordance with some embodiments.

### DETAILED DESCRIPTION

The claimed subject matter is now described with reference to the drawings, wherein like reference numerals are used to refer to like elements throughout. In the following description, for purposes of explanation, numerous specific details are set forth in order to provide a thorough understanding of the claimed subject matter. It may be evident, however, that the claimed subject matter may be practiced without these specific details.

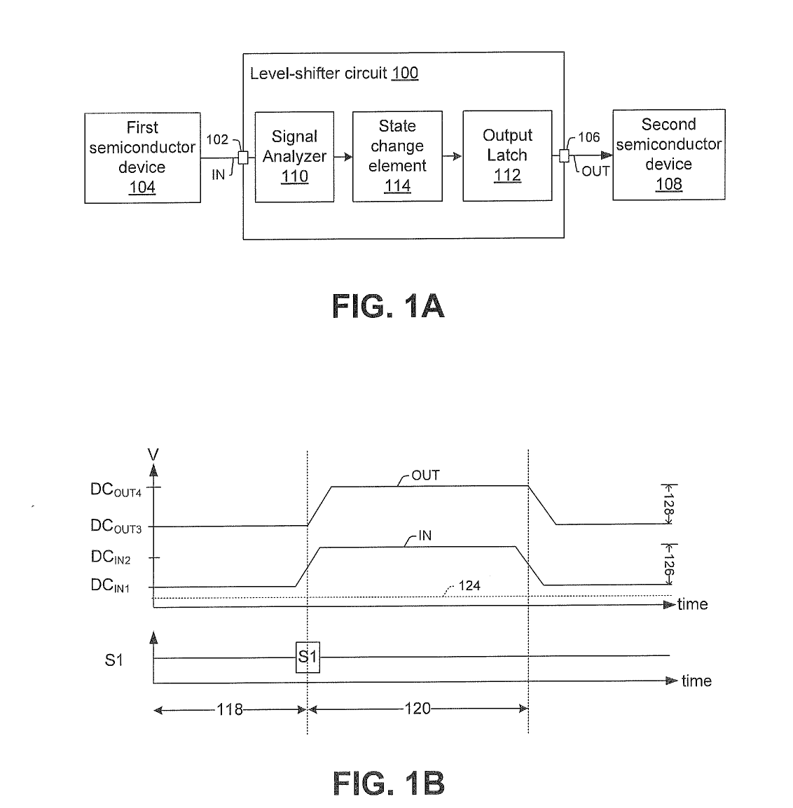

Some embodiments of the present disclosure relate to level shifters that provide improved response times and/or lower static power dissipation compared to conventional level shifters. FIG. 1A shows a level shifter circuit 100 in accordance with some embodiments. The level shifter circuit 100 includes an input terminal 102 coupled to a first semiconductor device 104, and an output terminal 106 coupled to a second semiconductor device 108. The first semiconductor device 104 is designed to operate over a first voltage range (see e.g., 126 in FIG. 1B), and the second semiconductor device 108 is designed to operate over a second, different voltage range (see e.g., 128 in FIG. 1B)). To transform the input voltage range to the output voltage range, the level shifter circuit 100 includes a signal analyzer 110, a state change element 114, and an output latch 112, all of which are operably coupled as shown.

As now discussed with regards to FIGS. 1A-1B collectively, after an input signal IN having the first voltage range has been received on the input terminal 102, the signal analyzer 110 detects whether the input signal IN changes state, and selectively asserts one or more change-of-state signals based thereon. The change of state element 114 helps sets a voltage level of the output signal OUT based on whether the change-of-state signal is asserted. In this manner, the level shifter circuit 100 can shift voltage levels and provide a suitable interface between semiconductor devices designed to operate at different voltage ranges.

For example, near the end of time window 118 in FIG. 1B, the signal analyzer 110 detects the input signal IN changes state from a first DC offset DCᵢₙ₁ to the second DC offset DCᵢₙ₂. Consequently, the signal analyzer 110 asserts a change-of-state signal S1. This change-of-state signal causes the output latch 112 to rapidly change its state, and in particular induces the output signal OUT to change from a third DC offset DCₒᵤₜ₃ to a fourth DC offset DCₒᵤₜ₄. Because the output latch 112 is “stateful”, the output signal OUT can remain at the fourth DC offset DCₒᵤₜ₄ throughout a second time window 120, often even if the first change-of-state signal S1 is de-asserted during the second time window 120. In some instances, rather than just provide a single change-of-state signal S1, the signal analyzer 110 can provide a first change-of-state signal to set the output signal to a first state as well as a second change-of-state signal to set the output signal to a second, different state.

For purposes of completeness, it will be appreciated that the output signal OUT is simply a level-shifted version of the input signal IN, and many variations are contemplated as falling within this disclosure. For example, in some embodiments the DC voltage offsets can be measured relative to a fixed reference voltage 124. In some embodiments, a first difference between the first and second DC voltage offsets 126 can be the same as a second difference between the third and fourth DC offsets 128; although in other embodiments these differences 126, 128 can be different. Further in some embodiments, the second DC offset DC_{IN2} can be lower than the third DC offset DC_{OUT3} (see e.g., FIG. 1B), but in other embodiments the second DC offset can be equal to the third DC offset, or the second DC offset can be higher than the third DC offset. In some implementations, the first difference 126 can be moving in time and/or the second difference 128 can be moving in time (e.g., the second difference 128 can be 5 V at one time and 3 V at a different time) Also, the differences 126 and 128 can move individually in several ways. For example, when differences 126/128 move individually, a difference between 126/128 can remain fixed (e.g., difference 126 can span 0V/5V at a first time when difference 128 spans 10V/15V, and difference 126 can span 10V/15V at a second time when difference 128 spans 20V/25V). The difference between differences 126/128 can also be moving in time (e.g., difference 126 can span 0 V/5V at a first time and difference 128 can span 10V/15V at the first time, and the difference 126 can span 5 V/10 V at a second time and difference 128 can span 30 V/33 V at the second time). In addition, although FIG. 1B shows an example of an up level-shifter where the output voltage is higher than the input voltage, in other embodiments, the level shifter can be a down-shifter wherein the output voltage is less than the input voltage. In some instances, the level shifter can also operate between completely different supply domains and thus, does not require a common VDD or a common GND. Other variations are also possible.

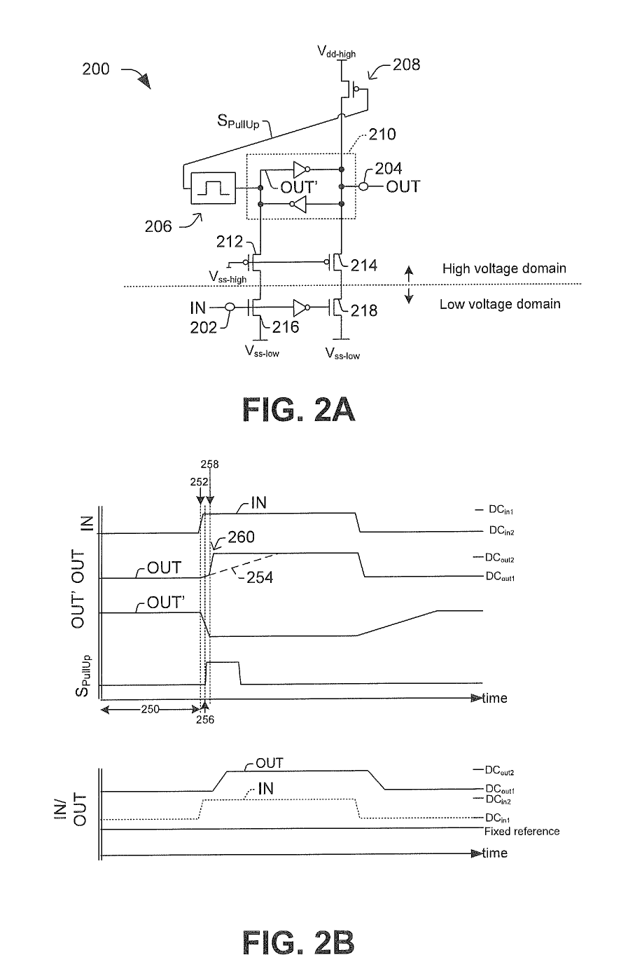

Referring now to FIG. 2A one can see a circuit schematic of a level shifter 200 in accordance with some embodiments. Like FIG. 1A's embodiment, the level shifter 200 includes an input terminal 202 and an output terminal 204. A signal analyzer 206, a change of state element 208, and an output latch 210 are operably coupled between the input and output terminals 202, 204. In FIG. 2A's embodiment, the output latch 210 comprises a pair of cross-coupled inverters, the signal analyzer 206 comprises a trigger circuit, and the change of state element 208 comprises a metal-oxide semiconductor field effect transistor (MOSFET). As will be appreciated in more detail below (e.g., in FIG. 2B) the level shifter 200 also includes other transistors (212-216) that actually convert the input voltage domain to the output voltage domain, however, these other transistors (212-216) in-and-of themselves suffer from slow output response times (e.g., slow pull-up times at the output terminal). Thus, the signal analyzer 206, change-of-state element 208, and output latch 210 help speed response times for the level shifter over previous solutions.

Referring now to FIGS. 2A-2B collectively, when the input voltage IN is low during time window 250, transistors 214 and 218 are on, which pulls the output terminal OUT down to DCₒᵤₜ₁ (e.g., near V_{SS-low}). At time 252, the input voltage IN increases, thereby turning transistor 216 on and pulling OUT′ down to DCₒᵤₜ₁ (e.g., near V_{SS-low}). Because transistors 212 and 216 are relatively large compared to the transistors in the cross-coupled inverters, OUT′ is pulled down relatively quickly. Further, however, because the inverters are relatively “weak” in and of themselves, they tend to pull the output voltage OUT up slowly (see dashed line 254). To improve this response time for pulling up to DCₒᵤₜ₂, the signal analyzer 206 monitors OUT′ and selectively asserts a pull-up signal S_{pullUp} at approximately time 256, wherein S_{pullUp} is based on the relatively fast OUT′ transition. Thus S_{pullUp} signal turns on the state-change element 208 at time 258, thereby helping to pull the output terminal up quickly (as shown by OUT signal during 260 above dashed line 254).

It will be appreciated that although FIG. 2A shows an up-level shifter, down-level shifters with improved response time are also contemplated as falling within the scope of the present disclosure. In one embodiment, such a down-level shifter could be implemented by flipping FIG. 2A's level shifter “up-side down” and interchanging n-type and p-type devices. More specifically, transistors 216 and 218 could be replaced with p-type transistors having drains coupled to V_{dd-high} (rather than the n-type transistors having sources coupled to V_{ss-low} as shown in FIG. 2A); and transistors 212 and 214 could be replaced with n-type transistors having gates tied to V_{dd-high}. The state-change element 208 can also be replaced by an n-type transistor having a source coupled to V_{ss-low}.

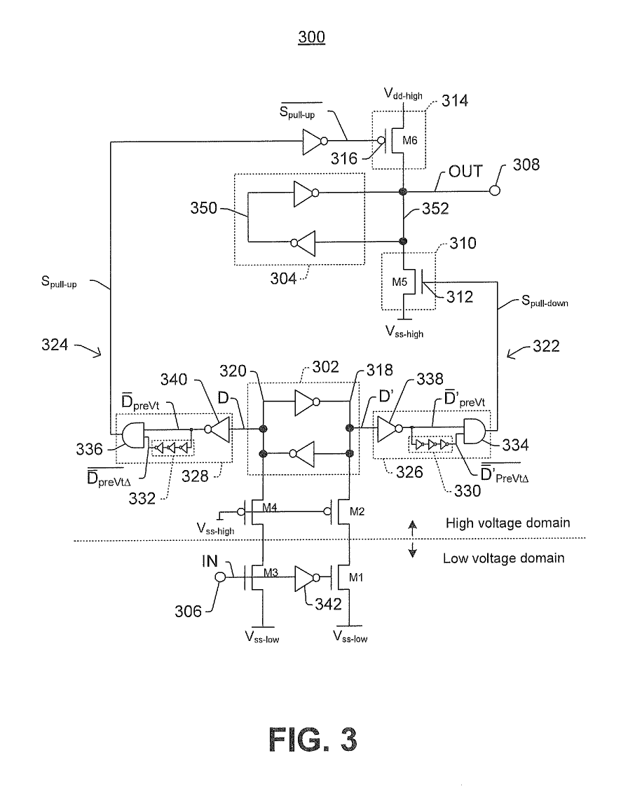

FIG. 3 shows a more detailed embodiment of a level shifter circuit 300 that includes a first latch 302 and a second latch 304, wherein the first latch 302 receives an input signal (IN) from an input terminal 306 and the second latch 304 outputs a latched output signal (OUT) to an output terminal 308. To set the state of the second latch 304, the level shifter circuit 300 includes a first state change element 310 having a first control terminal 312 and second state change element 314 having a second control terminal 316. The first and second control terminals (312, 316, respectively) are coupled to first and second complementary storage nodes (318, 320, respectively) via first and second control paths (322, 324, respectively). First and second trigger elements 326, 328 are included on the control paths 322, 324. These circuit elements can cooperatively “shift” a DC offset of the input signal such that the latched output signal is delivered with a second different DC offset (see e.g., discussion of level shifting in previous paragraph). Thus, the devices in the low voltage domain operate according to a first voltage range between V_{SS-low} and VD_{D-low} (e.g., corresponding to voltage difference 126 in FIG. 2), while the devices in the high voltage domain operate according to a second, different voltage range between V_{SS-high} and VD_{D-high} (e.g., corresponding to voltage difference 128 in FIG. 2).

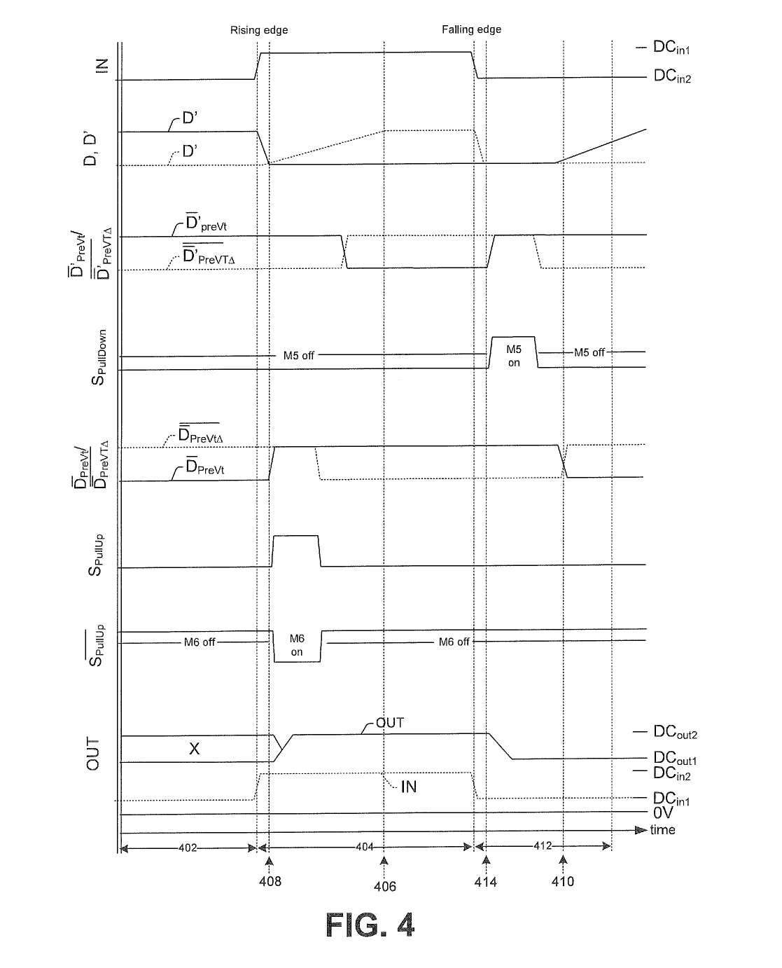

More detailed functionality for one implementation of FIG. 3's level shifter circuit is now discussed below with reference to FIGS. 3-4 collectively. For purposes of illustration, this embodiment is described with reference to a first trigger element 326 that includes an inverter 338, an AND gate 334, and a delay element 330 made up of three inverters in series; and a second trigger element 328 that includes an inverter 340, an AND gate 336, and a delay element 332 made up of three inverters in series. This implementation is only one example, and it will be appreciated that trigger circuits can take a number of different configurations and are not limited to those described and illustrated herein.

During time period 402 in FIG. 4, the input signal IN is received with a low voltage on the input terminal 306, and is inverted by inverter 342. The inverter 342 drives the voltage on the gate of M1 high, thereby activating M1 and pulling current through a first current path (through M1 and M2), and tending to pull signal D′ on the first complementary storage node 318 to a low voltage. The cross-coupled inverters in the first latch 302 drive signal D on the second complementary storage node 320 high. Because the signals D, D′ are constant during time period 402, the trigger circuits 326, 328 do not assert pull-up or pull-down signals on the control paths, ultimately resulting in the M5 and M6 being off during the first time period 402. Because both M5 and M6 are off, the output state of the second latch 304 is undefined during time period 402, as indicated by the X.

During time period 404, the input signal IN transitions to a high voltage, which causes M3 to conduct and pulls current through a second current path (through M3 and M4). This tends to pull signal D on the second complementary storage node 320 to a low voltage. Because the inverted input signal delivered to the gate of M1 is now low (M1 is off), the cross-coupled inverters in the first latch 302 ultimately drive signal D′ on the first complementary storage node 318 to a high value at time 406.

Because the delay element 332 offsets the waveforms D_{PreVt} and D_{PreVtBar} briefly, the AND gate 336 detects this change in state and pulses the S_{pullUp} signal, thereby making transistor M6 conduct and setting the state of the second latch 304 to a high state (e.g., DCₒᵤₜ₂) shortly after the start of time period 404.

During time period 412, the input signal IN transitions back to a low voltage, which turns M3 off. The inverter 342 again drives the voltage on the gate of M1 high, thereby activating M1 and pulling current through the first current path (through M1 and M2), and tending to slowly pull signal D′ on the first complementary storage node 318 to a low voltage. Because the delay element 330 offsets the waveforms D′_{PreVt} and D′_{PreVtBar} briefly, the AND gate 334 detects this change in state and pulses the S_{Pulldown} signal, thereby making transistor M5 conduct and setting the state of the second latch 304 to a low state (e.g., DCout1) shortly after the start of time period 412.

Although the first and second latches 302, 304 are illustrated in FIG. 3 as pairs of cross-coupled inverters, other types of latches could also be used. The same is true for the other illustrated embodiments. For example, gated or un-gated versions of SR NOR, SR NAND, JK, or T latches, among others, could be used, as could flip-flops or other bi-stable or -multi-state stable devices, all of which are contemplated as falling within the scope of the present disclosure. Also, although transistors M5 and M6 are illustrated as having their drain and source, respectively, tied to the output terminal 308, in other embodiments one or both of the transistors could have their source/drain regions coupled to the complementary storage node 350 of the second latch 304. For example, in another un-illustrated embodiment, transistor NMOS transistor M5 could be replaced with a PMOS transistor having a drain coupled to V_{DD-high} and a source coupled to 350 to selectively set the latched output signal OUT to a low voltage state.

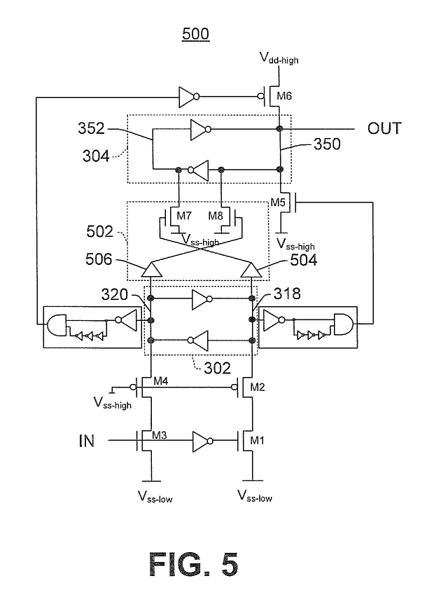

FIG. 5 shows another embodiment of a level shifter circuit 500 in accordance some aspects of this disclosure. In addition to the elements previously discussed in FIG. 3 (e.g., first latch 302 having first and second complementary storage nodes 318, 320; and a second latch 304 having third and fourth complementary storage nodes 350, 352), FIG. 5's level shifter circuit 500 includes static paths 502. These paths 502 can further help improve response times for the output signal OUT relative to the input signal IN, and help to ensure that the second latch 304 doesn't permanently latch “bad” data. A first static path includes a buffer 504 and a transistor M7, wherein the buffer 504 has an input coupled to the first complementary storage node 318 and wherein the transistor M7 has a drain coupled to the fourth complementary storage node 352. A second static path includes a buffer 506 and a transistor M8, wherein the buffer 506 has an input coupled to the second complementary storage node 320 and wherein the transistor M8 has a drain coupled to the third complementary storage node 350 and source coupled to V_{ss-high}.

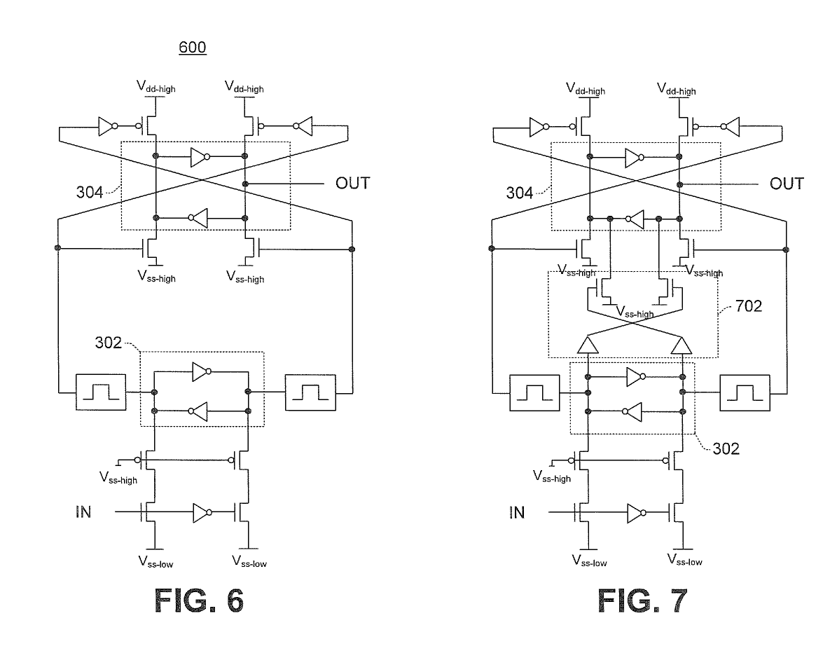

FIG. 6 shows another embodiment of a level shifter circuit 600. In this embodiment, the level shifter circuit 600 includes a pair of NMOS and PMOS transistors coupled to each complementary storage node of the second latch to help ensure quick response times. Typically, the level shifter circuit 600 will tend to respond more quickly to rising and falling input edges than FIG. 3's level shifter circuit 300, assuming the length-to-width ratios of the various transistors are kept the same between the two implementations. Although PMOS and NMOS transistors are illustrated in these embodiments, it will be appreciated by one of ordinary skill in the art that this disclosure is not limited to NMOS or PMOS transistors, and that other types of transistors could also be used (e.g., BJTs, fin-FETs, power FETs).

FIG. 7 shows another embodiment of a level shifter that is similar to the level-shifter circuit of FIG. 6, except that static paths 702 have been added between the first latch 302 and second latch 304.

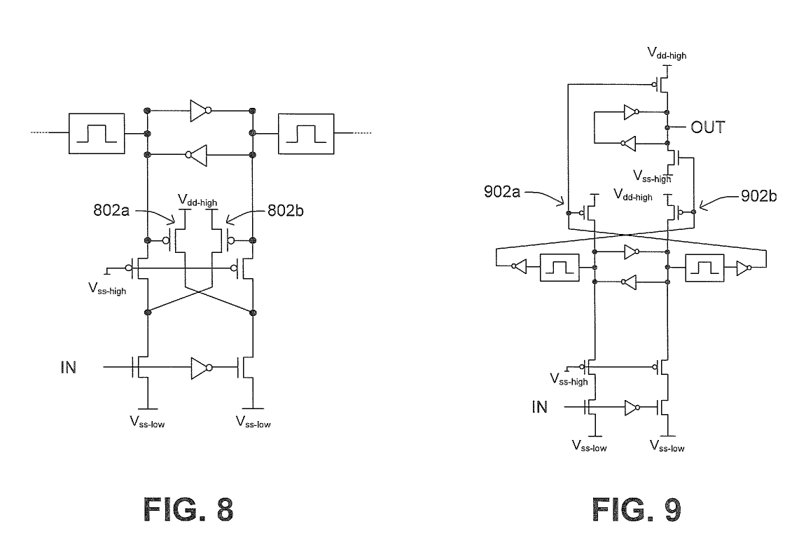

FIG. 8 shows still another embodiment wherein a pair of PMOS transistors 802 are coupled with respect to the first and second current paths near the input terminal. These PMOS transistors can also help improve response times for the level shifter circuits in some implementations.

FIG. 9 shows still another embodiment wherein a pair of PMOS transistors 902 are included in the dynamic paths. These PMOS transistors have control terminals that receive the pull-up or pull down signals from the trigger elements, and may also improve response times for the level shifter circuits in some implementations.

Although the disclosure has been shown and described with respect to one or more implementations, equivalent alterations and modifications will occur to others skilled in the art based upon a reading and understanding of this specification and the annexed drawings. The disclosure includes all such modifications and alterations and is limited only by the scope of the following claims. In particular regard to the various functions performed by the above described components (e.g., elements and/or resources), the terms used to describe such components are intended to correspond, unless otherwise indicated, to any component which performs the specified function of the described component (e.g., that is functionally equivalent), even though not structurally equivalent to the disclosed structure which performs the function in the herein illustrated exemplary implementations of the disclosure. In addition, while a particular feature of the disclosure may have been disclosed with respect to only one of several implementations, such feature may be combined with one or more other features of the other implementations as may be desired and advantageous for any given or particular application. In addition, the articles “a” and “an” as used in this application and the appended claims are to be construed to mean “one or more”.

Furthermore, to the extent that the terms “includes”, “having”, “has”, “with”, or variants thereof are used in either the detailed description or the claims, such terms are intended to be inclusive in a manner similar to the term “comprising.”

What is claimed is:

1. A level-shifter circuit, comprising:
an input terminal to receive an input signal having an input voltage level that varies between a first DC offset and a second DC offset;
a signal analyzer to selectively provide a change-of-state signal based on whether the input voltage level changes from the first DC offset to the second DC offset;
an output latch to output a latched output signal having an output voltage level that varies between a third DC offset and a fourth DC offset, wherein the output voltage level is set to the third or fourth DC offset based on the change-of-state signal.

2. The level shifter of claim 1, further comprising:
a state change element to selectively couple a storage node of the output latch to a supply voltage based on the change-of-state signal.

3. The level shifter of claim 2, wherein the state change element comprises a transistor, the transistor comprising:
a control terminal on which the change-of-state signal is received,
a second terminal coupled to a supply voltage; and
a third terminal coupled to the storage node of the output latch, wherein the third terminal selectively delivers approximately the supply voltage to the storage node based on the change-of-state signal.

4. The level-shifter of claim 1:
wherein the first, second, third, and fourth DC offsets are measured relative to a fixed DC potential; and
wherein a first difference between the fixed DC potential and at least one of the first DC offset or the second DC offset is different from a second difference between the fixed DC potential and at least one of the third DC offset or the fourth DC offset.

5. The level-shifter of claim 4, wherein the first and second DC offsets are separated from one another by a fixed difference, and wherein the third and fourth DC offsets are separated from one another by the same fixed difference.

6. The level-shifter of claim 1, wherein the first and second DC offsets are separated by a first difference, and wherein the third and fourth DC offsets are separated by a second difference that differs from the first difference.

7. The level-shifter of claim 1, wherein the first and second DC offsets are separated by a first, fixed difference, and wherein the second and third DC offsets are separated by a second difference that varies in time.

8. A level-shifter circuit, comprising:
a first latch to receive an input signal and to provide complementary data at first and second complementary storage nodes, wherein the complementary data are based on the input signal;
first and second state change elements having first and second control terminals, respectively, wherein the first and second control terminals are coupled to the first and second complementary storage nodes, respectively, via first and second control paths, respectively; and
a second latch to provide a latched output signal at an output terminal of the level-shifter circuit, wherein the output terminal is coupled to the first and second state change elements and wherein a change in state of the latched output signal is induced by the first and second state change elements.

9. The level-shifter of claim 8, wherein the output signal is set to a first state by the first state change element and is set to a second, different state by the second state change element.

10. The level shifter of claim 8, wherein the first latch comprises:
first and second current paths coupled to the first and second complementary storage nodes, respectively, wherein the first and second current paths carry first and second currents that are based on the input signal to set the complementary data at the first and second complementary storage nodes.

11. The level shifter circuit of claim 8, wherein the input signal changes in time between a first input DC offset and a second input DC offset.

12. The level shifter circuit of claim 11, wherein the first state change element sets the latched output signal to a first state when the input signal changes from the first DC offset to the second DC offset, and wherein the second state change element sets the latched output signal to a second state when the input signal changes from the second DC offset to the first DC offset.

13. The level shifter of claim 12, wherein during the first state the latched output signal has a third DC offset that is different from the first DC offset, and during the second state the latched output signal has a fourth DC offset that is different from the first, second, and third DC offsets.

14. The level shifter of claim 8, further comprising:
a first static current path coupling the first complementary storage node of the first latch to a third complementary storage node of the second latch; and
a second static current path coupling the second complementary storage node of the first latch to a fourth complementary storage node of the second latch.

15. A method for converting an input signal having a first DC offset to an output signal having a second DC offset, the method comprising:
detecting whether the input signal transitions from a first state to a second state, or vice versa;
selectively asserting a pull-up signal if the input signal transitions from the first state to the second state;
providing a latched output voltage based on the pull-up signal, wherein the pull-up signal increases the second DC offset of the output signal.

16. The method of claim 15, further comprising:
selectively asserting a pull-down signal if the input signal transitions from the second state to the first state;
wherein the pull-down signal decreases the second DC offset of the output signal.

17. A level-shifter circuit, comprising:
an input terminal to receive an input signal that changes between a first input DC offset and a second input DC offset in time;
a signal analyzer to selectively assert a pull up signal if the input signal changes from the first input DC offset to the second input DC offset, and to selectively assert a pull-down signal if the input signal changes from the second input DC offset to the first input DC offset;
an output latch element to provide an output signal that changes between a first output DC offset and a second output DC offset in time, wherein the output signal is set to the first output DC offset if the pull-up signal is asserted and is set to the second output DC offset if the pull-down signal is asserted.

18. The level shifter of claim 17, wherein the output latch element comprises a pair of cross coupled inverters.

19. The level shifter of claim 17, wherein the signal analyzer further comprises:
an input latch to receive the input signal and to provide complementary data at first and second complementary storage nodes, wherein the complementary data are based on the input signal.

20. The level shifter of claim 19, further comprising:
a first static current path coupling the first complementary storage node of the input latch to a third complementary storage node of the output latch; and
a second static current path coupling the second complementary storage node of the input latch to a fourth complementary storage node of the output latch.
